(19) United States
(12) Patent Application Publication
(10) Pub. No.: US 2025/0290190 A1
(43) Pub. Date: Sep. 18, 2025

(54) METHOD FOR MANUFACTURING OF ZIRCONIUM ALLOY CLADDING TUBES

(71) Applicant: KOREA ATOMIC ENERGY RESEARCH INSTITUTE, Daejeon (KR)

(72) Inventors: Hyun Gil KIM, Daejeon (KR); Sung Eun KIM, Seoul (KR); Dae Ho KIM, Daejeon (KR); Jongdae HONG, Daejeon (KR)

(21) Appl. No.: 18/576,153

(22) PCT Filed: Dec. 5, 2023
(86) PCT No.: PCT/KR2023/019839

§ 371 Date: Jan. 3, 2024

(30) Foreign Application Priority Data
Dec. 12, 2022 (KR) 10-2022-0172911

(51) Int. Cl. C23C 14/16; C23C 14/32

(52) U.S. Cl. CPC C23C 14/16; C23C 14/325

(57) ABSTRACT

The present disclosure attempts to provide a method of manufacturing a zirconium alloy cladding tube, which is capable of preventing a fine structure of a base material of a zirconium alloy from being changed by process heat, which is generated during a metal coating film deposition process using arc ion plating (AIP), thereby improving a bonding force between a coating layer and the base material, stacking the coating layer closely, and suppressing a change in performance of the base material. The method of manufacturing a zirconium alloy cladding tube according to the embodiment includes a cladding tube preparing step of preparing a cladding tube including a zirconium alloy material, a target preparing step, a vacuum heating step, and etching step, and a coating step and adjusts a change in fine structure to prevent recrystallization of the zirconium alloy on a surface of the cladding tube by adjusting a target condition, a preheating condition, a current condition, and a voltage condition.

### TECHNICAL FIELD

Provided is a method of manufacturing a zirconium alloy cladding tube.

### BACKGROUND ART

Cladding tubes for accident tolerant fuel (ATF) have been developed to prevent a hydrogen explosion by reducing the amount of production of hydrogen under a high-temperature water vapor environment in the event of a nuclear power plant accident. The ATF cladding tube particularly needs to be developed, focusing on improving oxidation resistance in the event of an accident, while meeting various performance conditions under extreme environments, such as corrosion resistance, creep resistance, stability under irradiation deformation, and issues related to storage and disposal of a cladding tube in the related art. However, in consideration of economic feasibility and rapid commercialization, the accident resistant cladding tubes are being developed worldwide by using a method in the related art of coating a surface of a zirconium (Zr) alloy cladding tube with an oxidation-resistant material.

To this end, the Korea Atomic Energy Research Institute has studied a method of treating a surface of a Zr alloy cladding tube in the related art by applying a 3D printing process and a coating method adopting an arc ion plating (AIP) technology. In particular, the AIP method is selected as a method of improving oxidation resistance by applying a Cr or CrAl alloy without damaging a base material of a commercially available zirconium alloy cladding tube, and the technologies related to the AIP method are being commercialized and developed.

However, even though the AIP process, which stacks a coating layer on the zirconium alloy cladding tube, is advantageous in that the base material is not changed, the AIP process has a problem in that a fine structure of the zirconium alloy cladding tube is changed by a process heat. When the fine structure of the zirconium alloy cladding tube is changed by the process heat, the physical properties, such as mechanical strength, deteriorate, which causes a problem with a structural function of a nuclear fuel cladding tube.

As a related preceding document, Korean Patent No. 2,161,584 discloses “Metal Coating Film with Excellent High-Temperature Oxidation Resistance and Corrosion Resistance and Method of Manufacturing the Same”.

### DISCLOSURE

### Technical Problem

The present disclosure attempts to provide a method of manufacturing a zirconium alloy cladding tube, which is capable of preventing a fine structure of a base material of a zirconium alloy from being changed by process heat, which is generated during a metal coating film deposition process using arc ion plating (AIP), thereby improving a bonding force between a coating layer and the base material, stacking the coating layer closely, and suppressing a change in performance of the base material.

The embodiment according to the present disclosure may be used to achieve not only the above-mentioned object but also other objects that are not specifically mentioned above.

### Technical Solution

An embodiment provides a method of manufacturing a zirconium alloy cladding tube, the method including: a cladding tube preparing step of preparing a cladding tube including a zirconium alloy material; a target preparing step of preparing a target, which includes a coating material applied onto a surface of the cladding tube, under a preset target condition; a vacuum heating step of disposing the cladding tube and the target in a chamber and vacuum-heating the cladding tube and the target under a preset preheating condition for an initial vacuum; a particle evaporating step of evaporating the particles of the coating material by generating the arc by supplying the current to the surface of the target under a preset current condition; and a coating step of uniformly coating the surface of the cladding tube with the coating material ionized by supplying the bias voltage under a preset voltage condition, in which a change in fine structure is adjusted to prevent the occurrence of recrystallization of the zirconium alloy on the surface of the cladding tube by adjusting the target condition, the preheating condition, the current condition, and the voltage condition.

### Advantageous Effects

According to the embodiment, the coating technology adopting the arc ion plating technology of the zirconium alloy may be applied, thereby increasing the bonding force between the coating layer and the base material during the process of manufacturing the zirconium alloy cladding tube, stacking the coating layer closely with high quality, improving the oxidation resistance, and preventing the fine structure of the zirconium alloy cladding tube from being changed by the process heat.

### DESCRIPTION OF THE DRAWINGS

FIG. 1 is a view schematically illustrating a process of manufacturing a zirconium alloy cladding tube by using a target setting condition according to an embodiment.

FIG. 2 is a view schematically illustrating a process of manufacturing a zirconium alloy cladding tube by using a target setting condition according to a comparative example.

FIG. 3 is a view schematically illustrating the process of manufacturing a zirconium alloy cladding tube by using the target setting condition according to the embodiment.

FIG. 4 is a view for comparing changes in fine structures of a cladding tube manufactured by using a target setting condition according to a first experimental example.

FIG. 5 is a view for comparing changes in fine structures of a cladding tube manufactured by using a target setting condition according to a second experimental example.

FIG. 6 is a view illustrating a change in fine structures of a cladding tube manufactured by using a target setting condition according to a third experimental example.

FIG. 7 is a view illustrating a change in fine structures of a cladding tube manufactured by using a target setting condition according to a fourth experimental example.

### MODE FOR INVENTION

An embodiment of the present disclosure will be described in detail with reference to the accompanying drawings so that those skilled in the technical field to which the present disclosure pertains may easily carry out the embodiment. The present disclosure may be implemented in various different ways, and is not limited to the embodiments described herein. In the drawings, a part irrelevant to the description will be omitted to clearly describe the present disclosure, and the same or similar constituent elements will be designated by the same reference numerals throughout the specification. In addition, a specific description of well publicly-known technologies will be omitted.

Throughout the specification, unless explicitly described to the contrary, the word “comprise/include” and variations such as “comprises/includes” or “comprising/including” will be understood to imply the inclusion of stated elements, not the exclusion of any other elements.

Hereinafter, a method of manufacturing a zirconium alloy cladding tube will be described in detail with reference to the drawings.

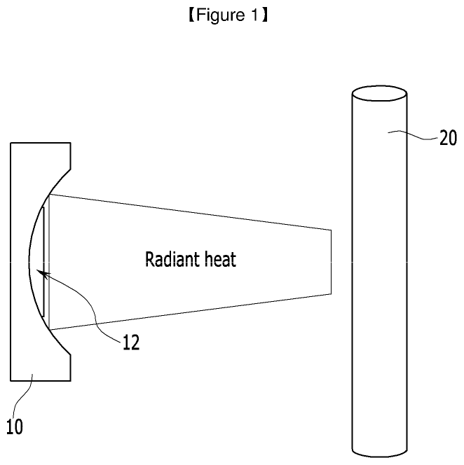

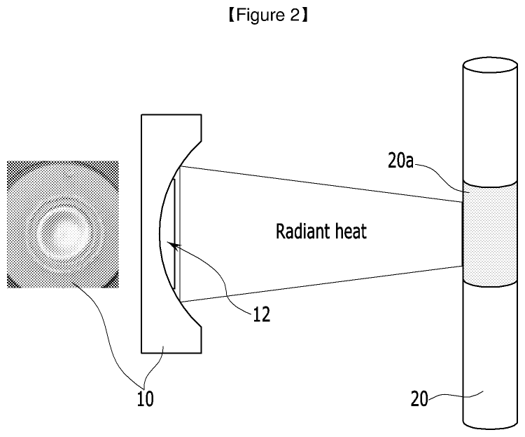

FIG. 1 is a view schematically illustrating a process of manufacturing a zirconium alloy cladding tube by using a target setting condition according to an embodiment, and FIG. 2 is a view schematically illustrating a process of manufacturing a zirconium alloy cladding tube by using a target setting condition according to a comparative example. The method of manufacturing a zirconium alloy cladding tube according to the embodiment will be described with reference to FIGS. 1 to 2. The method of manufacturing a zirconium alloy cladding tube according to the embodiment may include a cladding tube preparing step, a target preparing step, a vacuum heating step, an etching (cleaning) step, a particle evaporating step, and a coating step and easily adjust a change in fine structures in order to prevent the occurrence of recrystallization of a zirconium alloy on a surface of a cladding tube 20 by adjusting a preset target condition, a preheating condition, a current condition, and a voltage condition.

The cladding tube preparing step is a step of preparing the cladding tube 20 made of a zirconium alloy material. In this case, the cladding tube 20 may be interchangeably referred to as a zirconium alloy cladding tube or an accident tolerant fuel cladding tube.

The target preparing step is a step of preparing a target 10, which includes a coating material applied onto the surface on the cladding tube 20, under a preset target condition. In this case, the coating material may include an oxidation-resistant material. Further, the oxidation-resistant material may include one of or both Cr and a Cr alloy. A size of the target 10 may be set to 3 inches.

The vacuum heating step is a step of disposing the cladding tube 20 and the target 10 in a chamber 100 and vacuum-heating the cladding tube 20 and the target 10 under a preset preheating condition in order to implement an initial vacuum. In this case, a preheating temperature under the preset preheating condition may be set to 350 degrees or lower.

In the etching (cleaning) step, an arc is generated by supplying a preset current and a bias voltage to a surface of the target 10, such that particles of the coating material are evaporated, and surface foreign substances are removed. In the etching step, the current to be supplied to the target 10 may be set to 80 A or less, and the bias voltage may be set to 200 to 600 V, and the time may be set to 20 minutes or shorter, such that the change in fine structures of the target 10 may be minimized.

The particle evaporating step is a step of evaporating the particles of the coating material by generating an arc by supplying the current to the surface of the target 10 under the preset current condition. In the particle evaporating step, a washing function of evaporating the particles of the coating material and removing foreign substances from the surface of the cladding tube may be performed. In this case, as the preset current condition, the current to be supplied to the target 10 may be set to 80 A or lower, the bias voltage may be set to a range of 200 to 600 V, and the time may be set to 20 minutes or shorter. In the particle evaporating step, the change in fine structure (recrystallization) of the cladding tube 20 made of the zirconium alloy material does not occur when the time is set to 20 minutes or shorter even though the bias voltage is high.

The coating step is a step of uniformly coating the surface of the cladding tube 20 with an ionized coating material by supplying the bias voltage under the preset voltage condition in order to increase a deposition rate of the evaporated particles. In this case, the current to be supplied to the target 10 under the preset voltage condition may be set to 80 A or lower, and the bias voltage may be set to lower than 100 V. When the bias voltage increases, the etching occurs, which degrades deposition efficiency. In addition, when the vacuum-heating is performed at a preheating temperature of 350 degrees or lower, it is possible to prevent the deterioration in high-temperature oxidation resistance and the separation of a Cr—Al thin-film from an interface that may occur when the bias voltage is lower than 100 V. In the coating step, the coating may be performed for three hours or longer in order to obtain a Cr or Cr alloy coating layer with a thickness of 10 microns. For example, in order to uniformly coat the zirconium alloy with the Cr or Cr alloy of 10 microns or more, the coating time of about ten hours is required. This long-term coating may cause recrystallization of the base material of the zirconium alloy, which may reduce a change in fine structures of the target.

With reference to FIGS. 1 and 2, an example of the change in fine structures of the zirconium alloy cladding tube in accordance with an effect of the arc ion plating (AIP) process may be identified. For example, with reference to FIGS. 1 and 2, it is possible to compare recrystallization phenomena of the cladding tube 20 caused by a difference between the current and the bias voltage supplied to the target having a size of 3 inches. As in the embodiment in FIG. 1, the fine structure of the surface of the cladding tube 20 does not change in case that the target 10 has a size of 3 inches, the current is 80 A, and the bias voltage lower than 100 V is supplied. Reference numeral 12 indicates an evaporation portion of the target 10 with the size of 3 inches.

On the contrary, as in a comparative example in FIG. 2, the fine structure of the surface of the cladding tube 20 changes in case that the target 10 has a size of 3 inches, the current is 90 A, and the bias voltage of 120 V or higher is supplied.

As in the comparative example in FIG. 2, the fine structure of the surface of the cladding tube 20 changes in case that the target 10 having a size of 3 inches is applied, the current of 90 A is supplied, and the bias voltage of 120 V or higher is supplied. Therefore, it is necessary to identify the recrystallization caused by the change in fine structures of the surface of the cladding tube 20 by adjusting the size of the target 10 and adjusting a current forming region made by a magnetic field. Reference numeral 20a indicates a region in which the fine structure of the surface of the cladding tube 20 is changed.

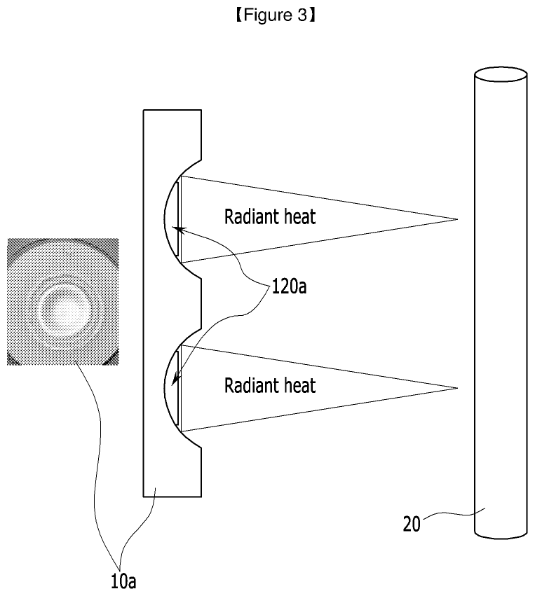

FIG. 3 is a view schematically illustrating the process of manufacturing a zirconium alloy cladding tube by using the target setting condition according to the embodiment. With reference to FIG. 3, the size of the target 10 may increase when the current and bias voltage to be supplied to the target 10 are respectively set to 90 A and 120 V. For example, the size of the target may be set to 5 inches, and the target having the size of 5 inches may rotate. Reference numeral 10a indicates the target having the size of 5 inches. Further, reference numeral 12a indicates a plurality of evaporation portions of the target 10a with the size of 5 inches. With reference to FIG. 3, as the target rotates, the arc is formed in a doughnut shape instead of a single point shape.

For example, in case that the current and bias voltage to be supplied to the target 10 are respectively 90 A and 120 V, the current may be controlled by the magnetic field so that the size of the target 10 is changed from 3 inches to 5 inches, and the arc rotates without being concentrated at a single point. In this case, a device for rotating the target may be provided.

The zirconium alloy varies depending on an alloy composition, but stress relieving or a partial recrystallization heat treatment is introduced and used. This heat treatment is intended to ensure properties such as mechanical strength and corrosion resistance in a furnace. The recrystallization of the zirconium alloy mostly starts at a temperature of 450 degrees or higher. When the zirconium alloy is maintained for a long period of time at a recrystallization temperature or higher, the recrystallization necessarily occurs. When the recrystallization occurs, the mechanical strength decreases, and the corrosion resistance is also changed as a size of a precipitate increases. In addition, when the recrystallization occurs partially, there is concern that a weak portion may be locally and mechanically deformed, and the cladding tube 20 is damaged because of a difference between creep and irradiation growth deformation amounts. Therefore, an undesired recrystallization of the cladding tube 20 deviates from the intended performance of the cladding tube 20.

The application of the oxidation-resistant material by using the arc ion plating is developed as a technology for manufacturing accident tolerant fuel that suppresses hydrogen explosion by suppressing oxidation under a nuclear reactor normal condition and an accident environment by coating a surface of a zirconium alloy cladding tube in the related art with an oxidation-resistant material with 50 microns or less. The arc ion plating has been advantageously applied and known as a technology for applying a high-melting point material without damaging or changing the base material. However, in case that the zirconium nuclear fuel cladding tube is coated with the oxidation-resistant material (Cr or Cr≥Al alloy), process heat may reach the zirconium alloy in accordance with process variables, which may cause recrystallization.

The embodiment may prevent the partial recrystallization in a longitudinal direction of the cladding tube 20. During a general process, radiant heat, which is generated when the surface of the target is melted, is transferred to the zirconium alloy because of a change in geometric shapes, which occurs at the time of applying the current and the bias voltage and consuming the coating target, such that an excessive temperature is accumulated.

In the embodiment, it is possible to solve the problem with the change in fine structures caused by the recrystallization of the zirconium alloy by limiting the preheating condition for the initial vacuum, the current and bias voltage condition applied during the coating, and the control condition of the radiant heat by controlling the size of the target and the consumption region. The embodiment may suppress the change in fine structures caused by the process heat generated at the time of coating the cladding tube 20 with the oxidation-resistant material (Cr or a Cr alloy, here, the Cr alloy includes a Cr-based alloy containing Cr—Al) during the arc ion plating process.

The configuration in which heat is generated during an arc ion plating vacuum deposition process and transferred to the cladding tube 20, which is a coating object, and the condition for the recrystallization will be described.
1) Preheating condition in vacuum of the chamber 100 in the vacuum heating step: the chamber 100 is heated by using a heater in order to implement a high-vacuum state in the chamber 100, such that gas molecules attached in the chamber 100 may be activated and easily discharged by a vacuum pump. In this case, a maximum temperature of the heater may be set to 350 degrees or lower. When the maximum temperature of the heater is set to 350 degrees or lower that is lower than 450 degrees of the recrystallization temperature of the zirconium alloy, an additional introduction of heat is caused by the application of the current and the bias voltage to the target 10, which is a subsequent process, such that an actual temperature of the zirconium alloy may increase, which causes the recrystallization. The preheating process is different from a deposition process to be performed subsequently, and a temperature during the deposition process is lower than about 200 degrees. In addition, the preheating process may be performed for about 20 to 30 minutes.
2) Condition of current to be supplied to the target 10 in the particle evaporating step: the arc may be generated on the surface of the target 10, and the target material may be evaporated. The arc heat is above 1,900 degrees to sufficiently ionize Cr and Cr alloy. The arc radiant heat, which is generated in this case, may cause the recrystallization of the zirconium alloy. Therefore, the current for generating the arc may be set to be supplied at 80 A or less that is a minimum condition for melting the target 10.
3) Bias voltage condition between the target 10 and the cladding tube 20 in the coating step: the particles are evaporated in the state in which the surface of the target 10 is ionized by the arc, and the evaporated particles are discharged to the outside from the target 10. In this case, when the bias voltage is applied, the speeds of the particles are increased, and the sizes of the evaporated particles are also increased. The high speeds and the increase in sizes of the particles transfer the heat of the particles to the cladding tube 20, which is a coating target, which increases a likelihood of recrystallization. Therefore, a maximum value of the bias voltage for increasing the deposition rate may be set to lower than 100 V.

The target 10 is additionally consumed, and the surface of the target 10 changes to a concave lens shape. When the surface of the target 10 changes to a curvature of a particular shape, the radiant heat generated by the arc current is concentrated in a particular region of the cladding tube 20, which increases a likelihood of recrystallization. Therefore, it is possible to prevent the occurrence of recrystallization, which is caused by the concentration of the radiant heat in the particular region, i.e., the target, by adjusting the concave lens shape formed when the surface of the target 10 is lost.

The arc ion plating for applying the accident tolerant fuel cladding tube 20 forms an ambience in a high-vacuum state by disposing the target 10 and a specimen in the chamber 100 and then heating the target 10 and the specimen. Further, the particles are evaporated by generating the arc by applying the current to the surface of the material (target) intended to be deposited instantaneously. Next, the specimen may be uniformly coated with the target material ionized by applying the bias voltage in order to increase the deposition rate of the evaporated particles.

However, the entirety or a part of the cladding tube 20 may be unintentionally recrystallized during the process of coating the cladding tube 20 with the oxidation-resistant material (Cr or Cr alloy).

The embodiment may optimize the condition for the vacuum-heating in the chamber 100 and the condition related to the current and the bias voltage to be supplied to the target 10, among the arc ion plating process variables, in order to solve the problem of recrystallization of the zirconium alloy. In addition, in order to prevent the integration of the radiant heat caused by the concave lens formed when the target 10 is consumed, it is possible to greatly change the size of the target 10 and remove a situation in which the arc current is concentrated in a single region by the magnetic field.

For example, the heating temperature may be set to be maintained to be 350 degrees or lower in the vacuum of the chamber 100 during the process. The current to be supplied to the target 10 may be set to be maintained to be 80 A or lower. Further, the bias voltage may be set to be maintained to be lower than 100 V. In this case, one or more of the set conditions such as the heating temperature, the target current, and the bias voltage exceed a set limit value, the problem of recrystallization of the zirconium alloy may occur.

The arc ion plating method according to the embodiment may be considered as a physical deposition method, and it is necessary to optimize a deposition condition for performing atom unit deposition by supplying the current and the bias voltage to the target 10.

In this case, the current to be supplied to the target 10 may be set to 80 A or lower, particularly 70 A or higher and 80 A or lower, and the bias voltage may be set to lower than 100 V, particularly 70 V or higher and lower than 100 V. The deposition rate may decrease in case that the value of the current to be supplied to the target 10 is lower than 70 A. Further, in case that the value of the current to be supplied to the target 10 is higher than 80 A, the sizes and number of droplets generated in a coating thin-film may increase.

Meanwhile, in case that the bias voltage to be supplied to the target 10 is lower than 70 V, the high-temperature oxidation resistance may deteriorate, and the coating thin-film may be separated from the interface. Further, when the bias voltage to be supplied to the target 10 is higher than 100 V, the deposition rate may remarkably decrease.

Because the acceleration of the evaporated material decreases as the size of the evaporation material increases during the deposition, the evaporated material cannot reach the target because of a collision with gas molecules. Therefore, it is possible to increase an operating pressure during the deposition, thereby reducing the probability that the ions and droplets generated in the target 10 collide with gas molecules. The operating pressure during the deposition may be set to 5 to 30 mTorr. The surface roughness and the droplet may increase when the operating pressure during the deposition is lower than 5 mTorr.

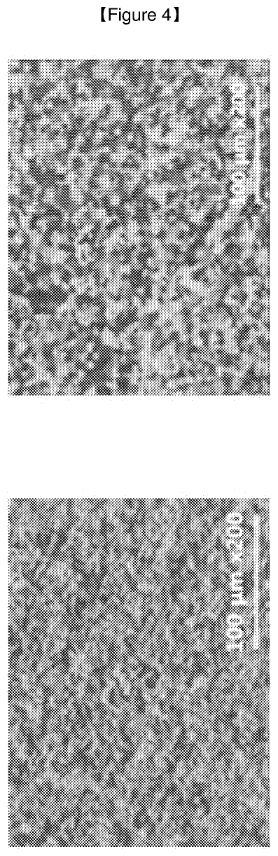

FIG. 4 is a view for comparing changes in fine structures of the cladding tube 20 manufactured by using a target setting condition according to a first experimental example. FIG. 4 illustrates the target with a size of 3 inches. With reference to FIG. 4, the changes in fine structures of the cladding tube 20 are compared by maintaining the current, which is supplied to the target 10, to 80 A or lower, and setting the bias voltage, which is supplied to the target 10, to 70 V. As illustrated in the left view in FIG. 4, the fine structure of the cladding tube 20 does not change in case that the current to be supplied to the target 10 is maintained to be 70 A, and the bias voltage to be supplied to the target 10 is set to 70 V. On the contrary, as illustrated in the right view in FIG. 4, the recrystallization occurs because of the change in fine structures of the cladding tube 20 in case that the current to be supplied to the target 10 is maintained to be 90 A, and the bias voltage to be supplied to the target 10 is set to 70 V.

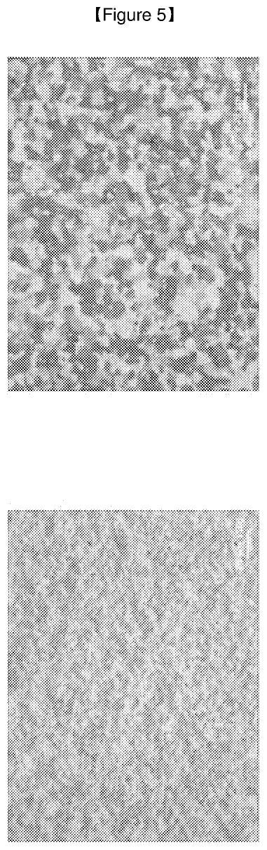

FIG. 5 is a view for comparing changes in fine structures of the cladding tube 20 manufactured by using a target setting condition according to a second experimental example. FIG. 5 illustrates the target with a size of 3 inches. With reference to FIG. 5, the changes in fine structures of the cladding tube 20 are compared by setting the bias voltage, which is supplied to the target 10, to lower than 100 V and 100 V or higher and setting the current, which is supplied to the target 10, to 70 A. As illustrated in the left view in FIG. 5, the fine structure of the cladding tube 20 does not change in case that the current to be supplied to the target 10 is maintained to be 70 A, and the bias voltage to be supplied to the target 10 is set to 90 V. On the contrary, as illustrated in the right view in FIG. 5, the recrystallization occurs because of the change in fine structures of the cladding tube 20 in case that the current to be supplied to the target 10 is maintained to be 70 A, and the bias voltage to be supplied to the target 10 is set to 120 V.

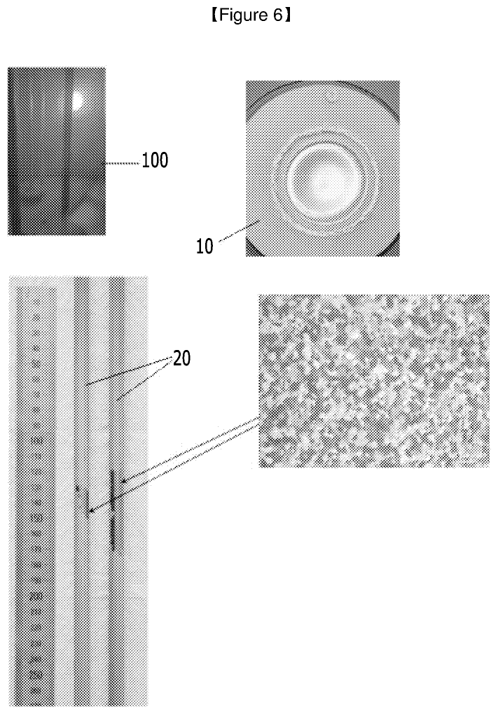

FIG. 6 is a view illustrating a change in fine structures of the cladding tube 20 manufactured by using a target setting condition according to a third experimental example. With reference to FIG. 6, the current and the bias voltage to be supplied to the target 10 may be respectively set to 90 A and 120 V, and the size of the target 10 may be set to 3 inches. In case that the current and the bias voltage to be supplied to the target 10 are respectively set to 90 A and 120 V, the arc is concentrated on a single portion on the target 10, and the fine structure of the cladding tube 20 changes, which causes the recrystallization.

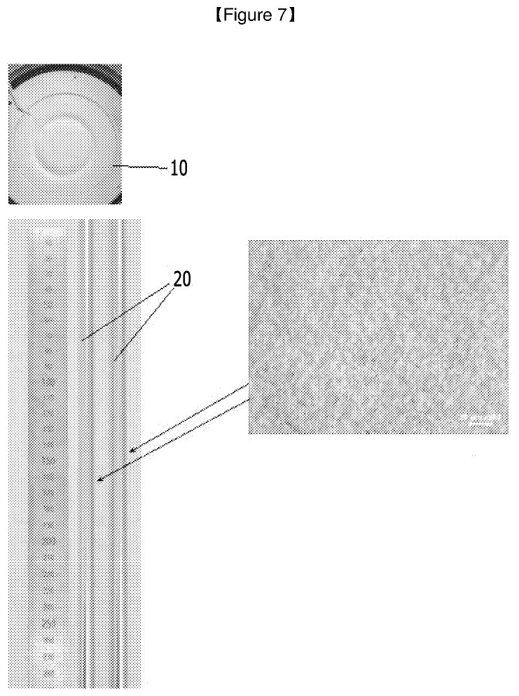

FIG. 7 is a view illustrating a change in fine structures of the cladding tube 20 manufactured by using a target setting condition according to a fourth experimental example. With reference to FIG. 7, the current and bias voltage to be supplied to the target 10a may be respectively set to 90 A and 120 V, and the size of the target 10a may be changed to 5 inches that is larger than 3 inches. Further, the fine structure of the cladding tube 20 does not change in case that the current and bias voltage to be supplied to the target 10a having the size of 5 inches are respectively set to 90 A and 120 V. This is because the current is controlled by the magnetic field so that the arc rotates without being concentrated on a single portion on the target 10a having the size of 5 inches.

The recrystallization may not occur when the current and bias voltage to be supplied to the target are low. The process efficiency becomes better as the size of the target increases, but the rotation is difficult to control in case that the current and bias voltage are high. The fine structure does not change when the current to be supplied to the target is 80 A or lower, the bias voltage is lower than 100 V, and the size of the target is 3 inches or more. However, in case that the size of the target is lower than 3 inches, e.g., 2 inches, the fine structure changes, and the process efficiency is low. The size of the target may be 10 inches or less. In case that the size of the target is larger than 10 inches, the target may be difficult to manufacture, and a yield of the target may decrease. For example, the target may have a size of 3 to 5 inches. The efficiency of the target having the size of 5 inches may be higher than the efficiency of the target having the size of 3 inches. The fine structure does not change in case that the current to be supplied to the target is higher than 80 A or in case that the bias voltage is 100 V or higher, the size of the target size is 5 inches or more, and the current is controlled by the magnetic field so that the arc rotates. Further, the fine structure does not change when the current is higher than 80 A or in case that the bias voltage is 100 V or higher, the size of the target is 4 inches, and there is an arc rotation magnetic field. Therefore, the fine structure does not change when the current is higher than 80 A or in case that the bias voltage is 100 V or higher, the size of the target is 4 inches or more, and there is an arc rotation magnetic field. Even in this case, the size of the target may be 10 inches or less in consideration of the manufacturability and target yield.

In the oxidation-resistant material deposition process of the cladding tube 20 applied to the accident tolerant fuel by using the arc ion plating process method, the change in fine structures of the cladding tube 20 affects mechanical and physical properties and corrosion properties, which makes it difficult to achieve the performance target of the cladding tube 20 used for the accident tolerant fuel. The embodiment may implement the coating technology capable of increasing the bonding force between the coating layer and the base material, stacking the coating layer closely with high quality, and preventing the change in performance of the base material in the coating technology adopting the arc ion plating technology of the zirconium alloy. The accident tolerant fuel needs to be applied to all future operable nuclear reactors to meet the requirements of the current EU Taxonomy that the accident tolerant fuel needs to be applied to the operable nuclear reactors after 2025. Therefore, the accident tolerant fuel cladding tube is inevitably applied to the operable nuclear reactor. The embodiment is a key technology related to the manufacturing of the accident tolerant fuel cladding tube and is expected to improve the safety of the operable nuclear reactor and provide a high economical effect implemented by the retention of the technology.

Although preferred examples of the present disclosure have been described in detail hereinabove, the right scope of the present disclosure is not limited thereto, and many variations and modifications of those skilled in the art using the basic concept of the present disclosure, which is defined in the following claims, will also belong to the right scope of the present disclosure.

1. A method of manufacturing a zirconium alloy cladding tube, the method comprising:
a cladding tube preparing step of preparing a cladding tube comprising a zirconium alloy material;
a target preparing step of preparing a target, which comprises a coating material applied onto a surface of the cladding tube, under a preset target condition;
a vacuum heating step of disposing the cladding tube and the target in a chamber and vacuum-heating the cladding tube and the target under a preset preheating condition for an initial vacuum;
an etching step of removing surface foreign substances by evaporating particles of the coating material by generating an arc by supplying a preset current and bias voltage to a surface of the target;
a particle evaporating step of evaporating the particles of the coating material by generating the arc by supplying the current to the surface of the target under a preset current condition; and
a coating step of uniformly coating the surface of the cladding tube with the coating material ionized by supplying the bias voltage under a preset voltage condition,
wherein a change in fine structure is adjusted to prevent the occurrence of recrystallization of the zirconium alloy on the surface of the cladding tube by adjusting the target condition, the preheating condition, the current condition, and the voltage condition.

2. The method of claim 1, wherein:
the coating material comprises an oxidation-resistant material.

3. The method of claim 2, wherein:
the oxidation-resistant material comprises one of or both Cr and a Cr alloy.

4. The method of claim 1, wherein:
a preheating temperature is set to 350 degrees or lower.

5. The method of claim 1, wherein:
in the etching step, the current to be supplied to the target is set to 80 A or lower, the bias voltage is set to 200 to 600 V, and the time is set to 20 minutes or shorter.

6. The method of claim 1, wherein:
the particle evaporating step, the current to be supplied to the target is set to 80 A or lower.

7. The method of claim 1, wherein:
in the coating step, the bias voltage to be supplied to the target is set to lower than 100 V.

8. The method of claim 1, wherein:
a size of the target is set to 3 inches or more and 10 inches or less.

9. The method of claim 1, wherein:
when the current to be supplied to the target is higher than 80 A in the particle evaporating step or when the bias voltage is 100 V or higher in the coating step, the target rotates, and a size of the target is set to 4 inches or more and 10 inches or less.
